(19) United States
(12) Patent Application Publication
(10) Pub. No.: US 2003/0002244 A1
(43) Pub. Date: Jan. 2, 2003

(54) Computer safety device and methods for increasing the safety of a person carrying the device

(76) Inventor: Mitko G. Mitev, Corvallis, OR (US)

Correspondence Address: HEWLETT-PACKARD COMPANY, Intellectual Property Administration, P.O. Box 272400, Fort Collins, CO, 80527-2400, US

(21) Appl. No.: 09/898,944

(22) Filed: Jul. 2, 2001

(51) Int. Cl. H05K 5/00

(52) U.S. Cl. 361/683; 312/223.2

(57) ABSTRACT

Methods and systems for increasing the safety of a person carrying a portable computer are described. In one embodiment, the safety device comprises a portable computer having a housing and a power source supported by the housing. At least one light-emitting device is connected to the power source and is configured to emit light responsive to the computer being carried. In another embodiment, the portable computer has a housing and at least one light reflecting safety structure attached to the housing.

### TECHNICAL FIELD

The present invention relates generally to methods and systems for increasing the safety of a person carrying a portable computing device.

### BACKGROUND

Every year in the United States, about 5,500 pedestrians and 1,000 cyclists are killed by motor vehicles and another 95,000 are injured. Sixty-five percent of these accidents occur in low light conditions. This is especially prevalent for children. More children between the ages of 5-14 die as a result of being struck by a motor vehicle than from any other cause, natural or accidental.

Accidents often occur because of poor visibility. Drivers can have a hard time seeing pedestrians or cyclists in low light conditions. For example, it takes 260 feet to stop a car going 60 MPH. A person wearing white clothing in the dark can be seen from approximately 180 feet away; even worse, a person wearing dark clothes can only be seen at 55 feet.

Accidents typically occur anywhere that vehicles and pedestrians cross paths. Typical accident locations include parking lots, crosswalks, sidewalks, and roadways. Consider the situation in which a child walks to and from school. In the course of their walk, they typically encounter many locations where accidents occur. For example, when they leave their home they may be required to cross several roads and crosswalks to reach their destination. Additionally, most schools have parking lots. Accordingly, the child may be required to cross a parking lot. Unfortunately, at the same time the child is walking to or from school, traffic to or from school tends to be highest. Specifically, parents who drive their children to school, as well as school buses carrying children contribute to the high traffic conditions during these times. Low visibility conditions can be particularly problematic during the winter months when the sun rises later and sets earlier.

To date, there are devices and mechanisms that pedestrians can use to increase their visibility when they walk in low light conditions. For example, light-colored clothing is typically worn to assure that drivers can see them, but as described above, this is often inadequate. Reflectors can be attached to clothing and can be effective at increasing visibility. A reflector can increase visibility 3-10 times as opposed to clothing alone. However, children often forget to wear the reflectors. Additionally, reflectors often get covered up by backpacks or other clothing and are easily lost or forgotten.

Accordingly, this invention arose out of concerns for the safety of pedestrians and bicyclists traveling in low light conditions in close proximity to vehicles.

### BRIEF DESCRIPTION OF THE DRAWINGS

FIG. 1 diagrammatically illustrates one environment in which various described embodiments can be utilized.

FIG. 2 is a view of an exemplary computer in the open position.

FIG. 3 is a perspective view of an exemplary computer in the closed position.

FIG. 4 is a plan view of the top or bottom surface of an exemplary computer in accordance with one embodiment.

FIG. 5 is a plan view of the top or bottom surface of an exemplary computer in accordance with one embodiment.

FIG. 6 is a plan view of the top or bottom surface of an exemplary computer in accordance with one embodiment.

FIG. 7 is a plan view of the top or bottom surface of an exemplary computer in accordance with one embodiment.

FIG. 8 is a perspective view of an exemplary computer in the closed position.

FIG. 9 is an exemplary view of the front, back, or side surface of an exemplary computer.

FIG. 10 is a flow diagram that describes a method in accordance with one embodiment.

FIG. 11 is a flow diagram that describes a method in accordance with one embodiment.

FIG. 12 is a block diagram that illustrates an exemplary safety device.

### DETAILED DESCRIPTION

### Overview

In accordance with the embodiments described below, reflective surfaces or structures, and/or light-emitting devices are affixed to, adhered to, or otherwise form part of the housing of a portable computer to increase the visibility of a person carrying the computer.

The computer can comprise any suitable portable computer, examples of which include, but are not limited to, portable computers such as a laptop or notebook computer, hand held computers such as Palm Pilot brand computers, game or entertainment computers such as Game Boy brand computers, and the like.

### Exemplary Embodiment

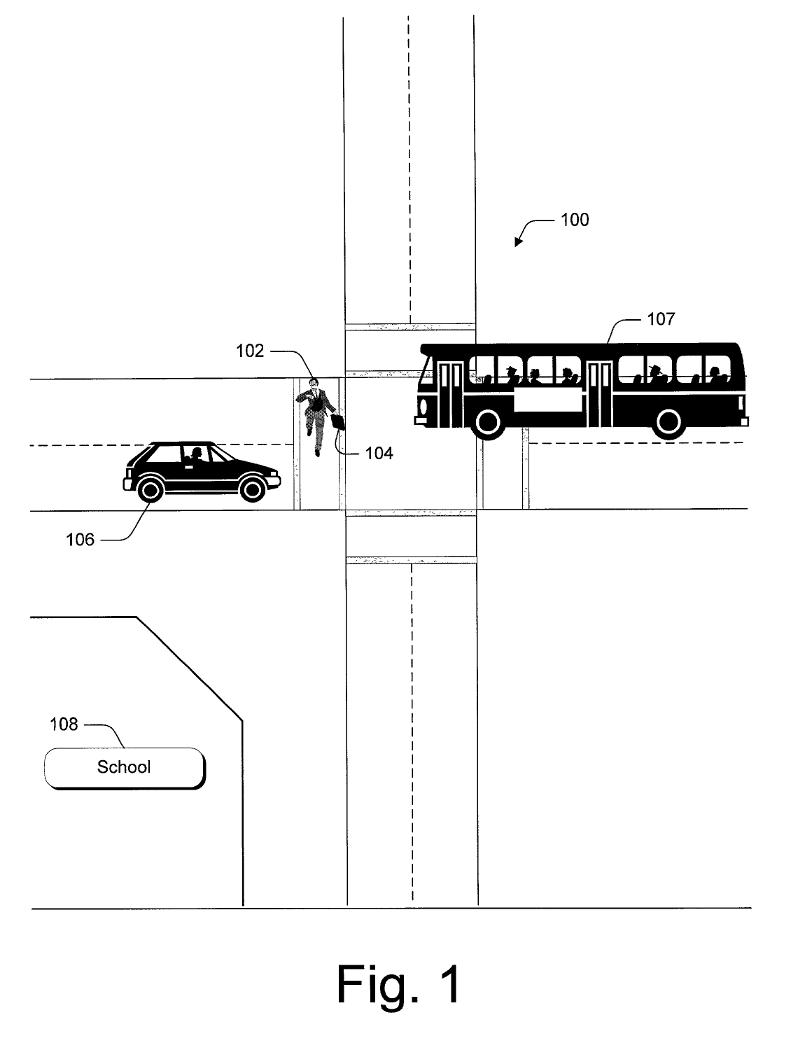

FIG. 1 shows an exemplary environment in which the various embodiments described below can be used. It shows an intersection generally at 100. In the intersection is a pedestrian 102. The pedestrian is carrying a notebook computer 104. Also shown are a car 106, a bus 107, and a school 108.

If the pedestrian is crossing the intersection in low light conditions his/her visibility to drivers may be inadequate. This can present a hazard not only to the pedestrian, but also to the drivers of the various vehicles who may likely encounter the pedestrian.

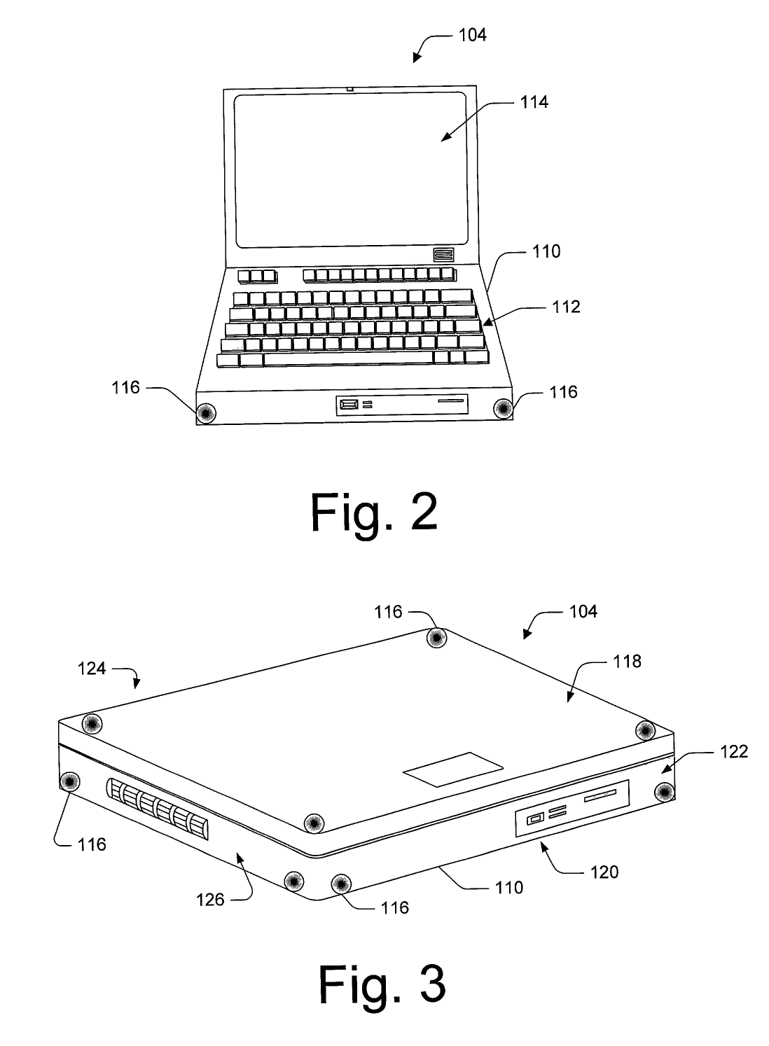

FIGS. 2-12 show various embodiments which can assist in ensuring that a pedestrian carrying a portable computer has a much higher chance of being seen by the drivers of the various vehicles and others who may encounter the pedestrian.

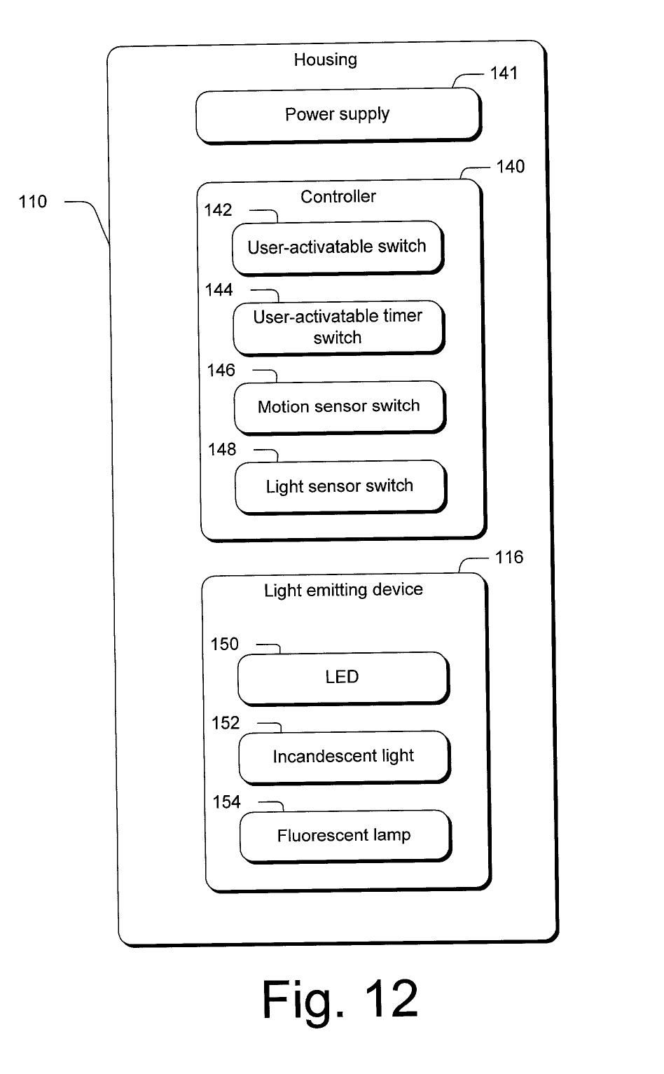

FIG. 2 shows an exemplary notebook computer 104 in the open position. The computer has a housing 110, a keyboard 112, and a display 114. It also shows a light-emitting device 116. The light-emitting device can be any device which gives off enough light to increase the visibility of a person carrying the computer to others in the vicinity. Various embodiments of light-emitting device are further described in FIG. 12.

FIG. 3 shows the same exemplary computer 104 as FIG. 2, but in the closed position. The closed position is the position in which the computer is usually transported or carried as shown by the pedestrian in FIG. 1. FIG. 3 shows generally, a top surface 118, a bottom surface designated 120 but not specifically visible, a front surface 122, a back surface designated 124 but not specifically visible, and side surfaces 126. As can be seen, the front, back, and side surfaces extend between the top and bottom surfaces. The shape of the computer shown in FIG. 3 is generally rectangular with planar surfaces. This shape is the most common shape and is easily recognizable. It is possible, however, for the geometric shape of the computer to be different from that shown in FIGS. 2 and 3. For example, the housing can have top and bottom surfaces with a round or oval perimeter. Further, the top and bottom surfaces can be convex or other non-planar shapes. The sides which extend between the top and bottom surfaces can be non planar. Further, the side surfaces can be curved so that at the midpoint between the top and bottom surfaces, the side surfaces extend farther radially than the top and bottom surfaces. Accordingly, the illustrated shape is not essential to the present embodiments. Rather, one skilled in the art will recognized many other configurations which can be equally satisfactory.

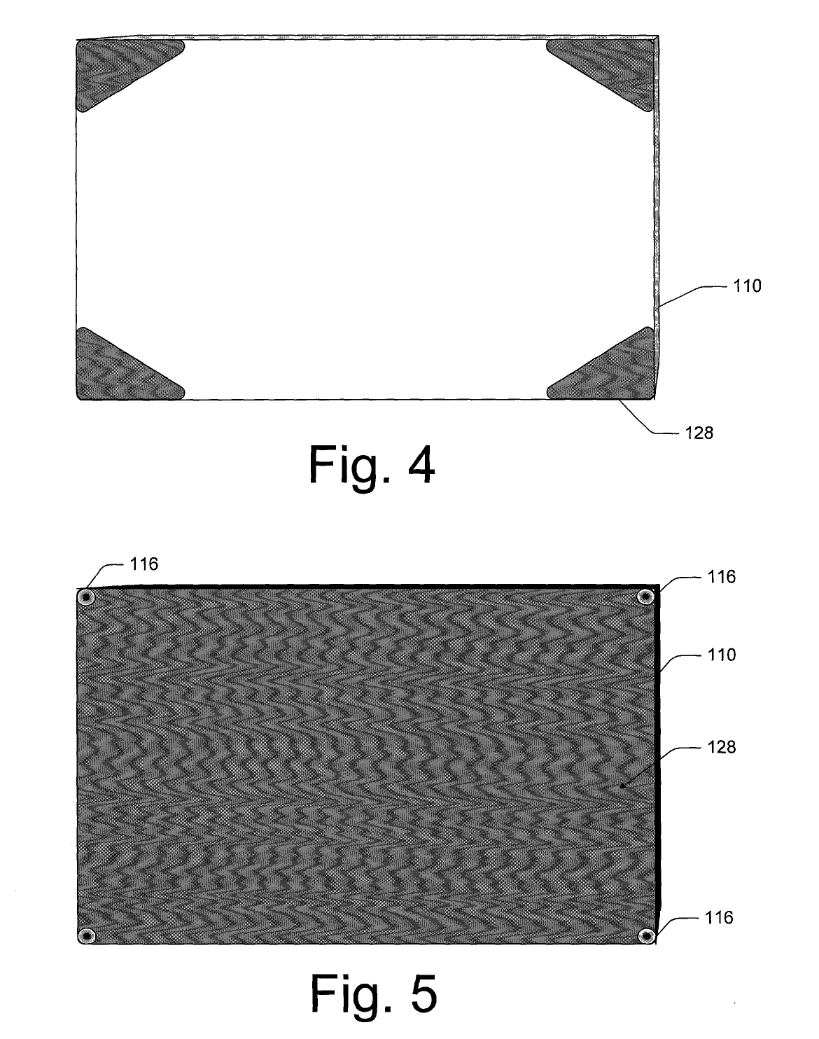

FIGS. 4-7 are views of the computer housing 110, which is in the closed position as shown in FIG. 3. The surface shown in FIGS. 4-7 can be either the top surface 118 or the bottom surface 120. The features about to be described can be adapted for use on the front, back, and side surfaces and various combinations of these surfaces.

FIG. 4 further shows a reflector 128 positioned on the housing 110. In this embodiment, there are multiple reflectors affixed to, adhered to, or otherwise forming part of the housing. The reflectors reflect light in a manner that promotes the safety of an individual carrying the computer. They do this by making the individual more visible to others in the individual's proximity than the individual would otherwise be without the reflectors.

The term reflector can mean any reflective structure or reflective surface. It is not critical to the present embodiments what form the reflector takes, nor is it critical how the reflector is fastened to, affixed to, adhered to, or otherwise forms part of the computer. Rather, one skilled in the art will recognize many satisfactory embodiments that can be within the spirit and scope of the claimed subject matter.

For example, one type of suitable reflector can be an adhesive backed reflective tape that can be applied to the housing. Another suitable example is reflective paint which can be applied to desired portions of the housing. Yet another example can include various reflective structures which are available for mounting on various objects. The structures can be mechanically fastened to the housing or molded into the housing during the manufacturing process to name just a few satisfactory embodiments. Additionally, suitable reflectors can be mounted on the computer's housing by means of any type of fastening mechanism such as loop and pile fasteners, commonly referred to as “Velcro”.

Some types of reflectors can more efficiently do their jobs than others. A specular reflector is one which reflects the light at the inverse of the angle at which is received. Generally, if light from a vehicle's headlights strikes a specular reflector from an orthogonal direction, the light is reflected back in the direction from which it came. This increases the chance of the vehicle's driver seeing the reflected light. Common examples of specular reflectors include those commonly seen on bicycles and roadway signs. The opposite of specular is diffuse. For example, white paint and white clothing reflect much of the light which strikes it. However, the light is reflected in many different directions, i.e. the light is diffused. This decreases the percentage of light which can reflect back toward the light source. This is one reason why white clothing is not as effective at increasing visibility even though the clothing reflects a high percentage of the light which strikes it. Therefore, in some embodiments it can be advantageous to use reflectors with a high degree of specularity.

Like FIG. 4, FIG. 5 shows a reflector 128 affixed to, adhered to, or otherwise forming part of the housing 110. FIG. 5 shows the majority of the depicted surface covered by a reflector. Additionally, FIG. 5 shows several light-emitting devices 116 positioned on the housing.

FIGS. 4 and 5 show but two examples of how reflectors and/or light-emitting devices can be used to enhance the visibility of a computer housing and, in turn, the safety of an individual carrying the computer. In FIG. 4, reflectors are positioned in a discrete pattern on the four corners of the depicted top or bottom surface. This pattern (as well as other patterns which are simply too numerous to show) can be applied to multiple surfaces. This increases the chances that the reflectors can be seen when the computer is carried in different dispositions by an individual. For example, assume that the pattern of FIG. 4 is applied to both the top and bottom surfaces of a computer housing. If the person carrying the computer holds it in the middle, under his/her arm as one might carry a book, some of the four corner reflectors shown in FIG. 4 can remain visible (e.g. those reflectors that face generally away from the individual) to others in the individual's proximity. The same logic applies to FIG. 5 in that if some of the reflective surface is covered by the user, other portions of the reflective surface can remain visible.

It is not essential to these, or other embodiments, for the reflectors or light-emitting devices to be positioned directly on the housing, or, indirectly on structures such as reinforcing armor, handles, feet, etc. Additionally, the reflectors and/or light emitting devices can be molded right into the housing during manufacture. To be sure, one skilled in the art will recognize that there are many different ways for such reflectors or light emitting devices to be mounted.

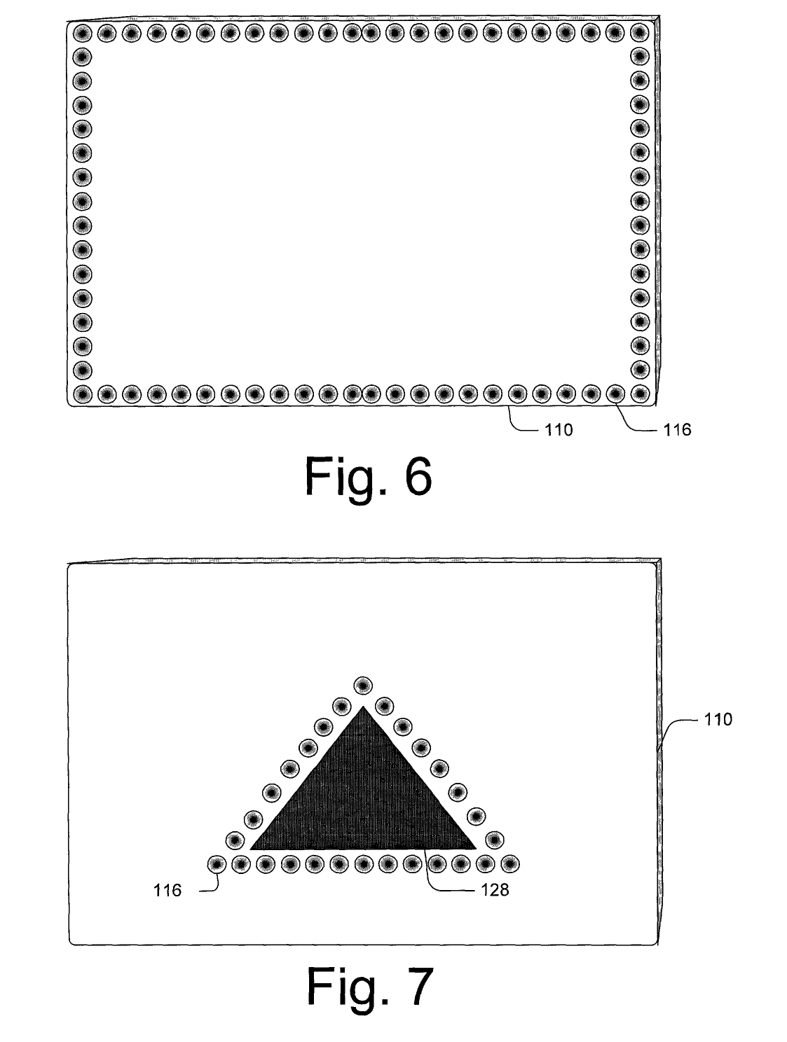

FIG. 6 shows multiple light-emitting devices 116 positioned on housing 110 and configured to emit light of sufficient magnitude to be perceived by others when the housing is closed and the computer is carried by an individual.

The pattern of light-emitting devices depicted in FIG. 6 can be applied to both the top and bottom surfaces. A similar arrangement of light-emitting devices can be disposed along individual edges of the other housing surfaces. To provide an extra measure of safety, multiple light-emitting devices can be positioned on all faces or surfaces of the computer housing. In this way at least some of the light-emitting devices can be visible regardless of how the computer is carried

For example, consider again FIG. 1. Here the person carrying the computer is carrying it so that what are defined as the top and bottom surfaces, 118 and 120 respectively, are now generally facing the approaching car and bus. The side surfaces generally face the two lanes of travel which are presently unoccupied. In the present example because each of these surfaces has multiple light-emitting devices the computer can be perceived from each direction of travel.

To further assure that the light-emitting devices are perceived by others near the person carrying the computer, the light-emitting devices can be configured to blink in a predefined pattern.

For example, drivers can be more likely to notice a change in their environment as opposed to things which are steady or constant. To this end, in one embodiment, all of the light emitting devices can blink on and off together. This increases the likelihood that the lights will be noticed or perceived by drivers and others in the proximity of the computer and the person carrying it. Other blinking patterns can, of course, be utilized.

FIG. 7 shows an embodiment where the light-emitting devices 116 and reflectors 128 are placed in a pattern together. In this embodiment, the reflector is shaped in the universally recognized warning triangle. The light-emitting devices are positioned around the periphery of the reflector so that they too are in the shape of the warning triangle. In this embodiment light given off by the light-emitting devices can be reflected by the reflector away from the computer, thereby increasing the likelihood of the computer being seen by others.

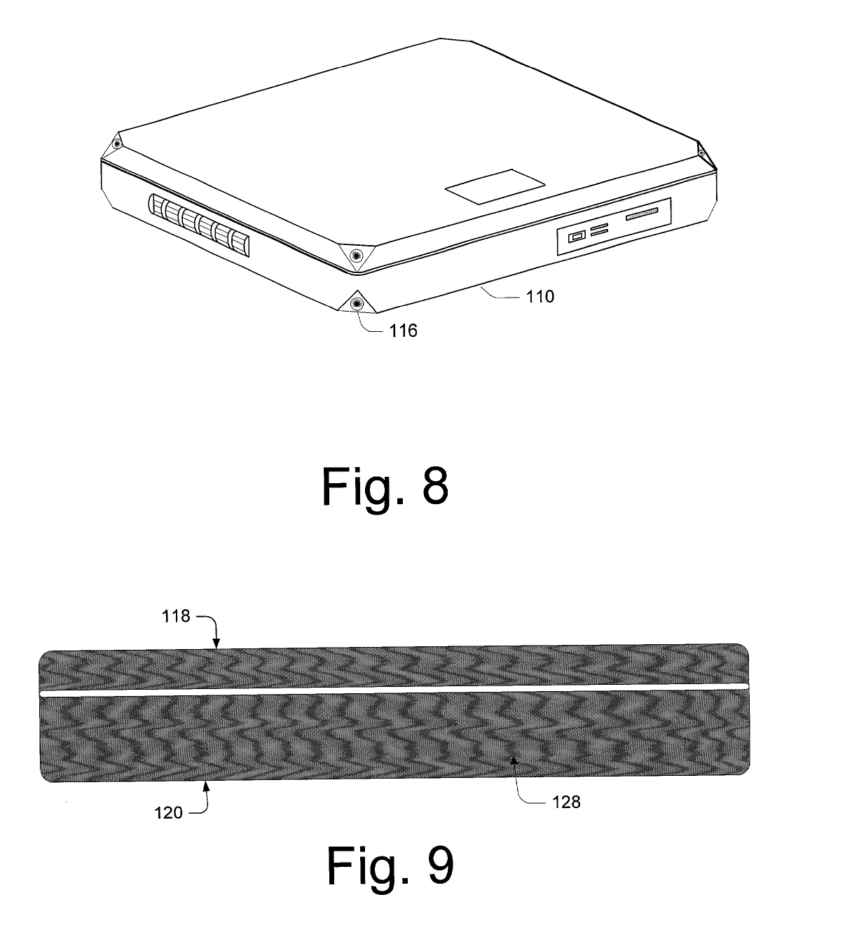

FIG. 8 shows an exemplary embodiment which can utilize fewer light-emitting devices. In this example, the light-emitting devices are not positioned on the generally planar surfaces described above. Specifically, if the surfaces described above (top, bottom, front, back, and sides) are assumed to be generally planar, then the light-emitting devices 116 depicted in FIG. 8 are positioned on surfaces which intersect at least two of the generally planar surfaces described above.

The positioning of the light-emitting devices depicted in FIG. 8 is one non-limiting example which allows at least some of the light emitting devices to be visible from multiple directions relative to a user, when the computer is carried by the user. This is best illustrated by referring back to FIG. 1 and assuming that the computer depicted in the illustration comprises the FIG. 8 computer. In this case, when the computer is held as depicted in FIG. 1, some of the light-emitting devices pictured in FIG. 8 can be visible to both the car 106 and the unused lanes at the bottom of the page. Yet other light emitting devices can be visible to the bus 107 and the unused lanes at the top of the page.

FIG. 9 shows how a reflector or reflectors can be positioned on the front, back, or sides of the computer housing which as described above extend between the top surface 118 and the bottom surface 120. In this non-limiting embodiment, the majority of the surface area is covered by the reflector. Of course, this same embodiment can be used on the top and bottom, the distinction here being only for the purpose of illustration.

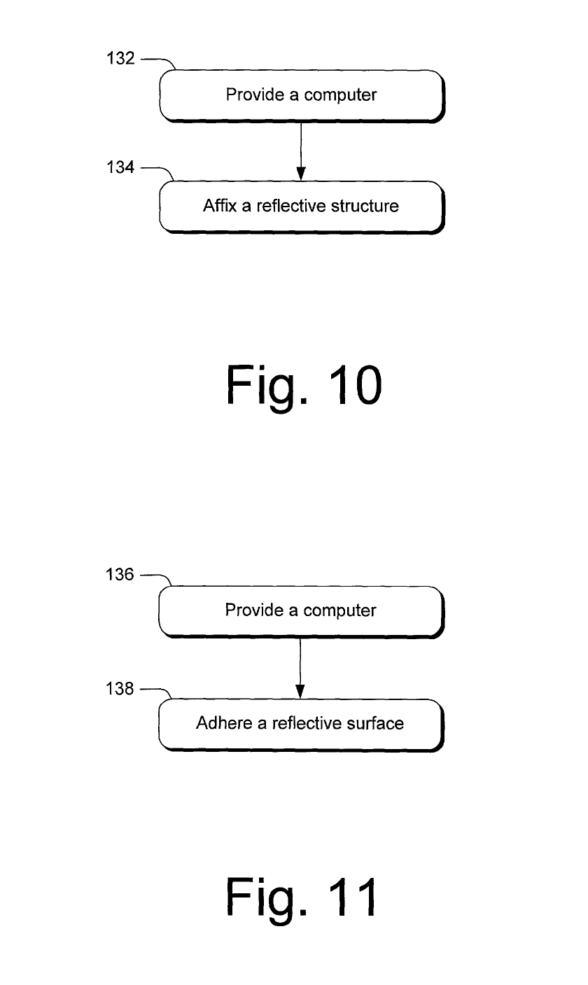

The above described Figures show various examples of how reflectors can be placed on a computer housing in various embodiments. FIG. 10 is a flow diagram that describes a method for enhancing the safety of a computer user in accordance with one embodiment. Block 132 provides a computer having a housing. Block 134 affixes at least one reflective structure to the housing. The reflective structure is desirably positioned to reflect light so that it can be seen by others when the computer is carried. This block can be carried out in any suitable way. For example, the reflective structure can be applied by hand. Alternately, the reflective structure can be applied by a machine as, for example, in an assembly line setting. As noted above, the reflective structure can be affixed using any suitable affixing technique and/or affixing structures.

FIG. 11 is a flow diagram that describes a method for enhancing the safety of a computer user in accordance with one embodiment. Block 136 provides a portable computer having a housing. Block 138 adheres at least one reflective surface to the housing. The reflective surface is desirably positioned to reflect light so that it can be seen by others when the computer is carried. This block can be carried out in any suitable way. For example, the reflective surface can be self-adhesive reflective strips which are applied by hand, reflective paints or coatings which are applied as a liquid which adhere to the computer, or reflective surfaces which are glued on to the computer.

Several different embodiments of reflectors and or light-emitting devices have been described above. When light emitting devices are used it can be advantageous to be able to control the functioning of the devices. For example, a computer user might find the light-emitting devices distracting if they were on while he/she was using the computer. Additionally, the devices could drain the battery or power supply if they were on all the time. FIG. 12 illustrates one embodiment that permits control of the light emitting devices.

In this embodiment, the computer described above has a controller 140 coupled to a power supply 141. The controller can be further coupled to one or more light-emitting devices 116 to control whether the light-emitting devices are on or off.

In one embodiment, the controller can be a user-activatable switch 142. In this embodiment a computer user can push a button or other type of switch to activate the light-emitting device and the computer is ready for the commute. In another embodiment, the controller can be a user-activatable timer switch 144. This embodiment can be activated as described above, but can be set to turn off automatically after a definable period of time. For example, this embodiment can avoid the unfortunate possibility of draining the power supply if a user forgets to turn off the switch when arriving at a destination.

In another embodiment, the controller can be a motion sensor switch 146. Any suitable motion sensor switch can be used. Motion sensor switches are widely known and commercially available and will not be discussed further here. In this embodiment when the computer is placed on a stationary surface the light-emitting devices can be switched off (e.g. automatically), but when the motion sensor switch senses a definable amount of movement, the light-emitting devices can be switched back on. This embodiment can require no user attention or intervention at all. Specifically, upon reaching a destination, the motion sensor switch can detect a lack of motion and the light-emitting devices can be automatically turned off. Consider this embodiment and the following aspects.

Assume that a student is getting ready for school in the morning and picks up his/her portable computer which has been sitting by the door. Up to this point, the motion detected by the motion sensor switch has been below a definable threshold. Accordingly, the light-emitting devices are in the off position. When the computer is picked up, the motion sensor switch detects the motion and switches on the light-emitting devices. The student carries the computer to the bus stop with the light-emitting devices emitting light as they are supposed to. Once on the school bus, the motion might fall below the definable threshold and, accordingly, the light-emitting devices can be automatically switched-off. When the school bus arrives at the school and the student disembarks, the motion sensor switch again senses the motion and activates the light emitting devices thus ensuring their operation when, for example, the student crosses a busy school parking lot to talk to friends. When the computer is used on a desk during the day, the detected motion can be below the threshold and so the light-emitting devices can be switched off. At the end of the day, the student may stay after school for sports or other activities and have to walk home in the dark. The student might be tired after a busy day and forget to turn on a manual switch. With the motion sensor switch, however, the light-emitting devices can be automatically switched on and the student is much more visible to vehicles than he/she otherwise would be.

In still another embodiment, the controller can be a light sensor switch 148. Light sensor switches are widely known and commercially available and will not be discussed further here. The light sensor switch can allow the light-emitting devices to be activated only when the ambient light falls below a predetermined threshold. This allows the light-emitting devices to come on automatically when a user travels in dark or low light conditions, but prevents the light-emitting devices from needlessly being illuminated during normal daylight conditions.

The described embodiments can be more effective when used in combination. For example, it can be beneficial to have the controller comprise both a motion sensor switch and a light sensor switch. In this embodiment, the light-emitting devices can be illuminated only when the motion detected by the motion sensor switch is above a predetermined threshold and the light level detected by the light sensor switch is below a predetermined level. With this combination, if the device is carried in daylight conditions the light emitting devices can remain off. If the computer is later placed in a dark cabinet the light-emitting devices would remain off, yet if evening came, and the computer was carried home, the predetermined conditions for both the light sensor switch and the motion sensor switch can be met and the light-emitting devices can be illuminated. This maximizes user safety and keeps the safety device very user friendly.

The above discussion has dealt generally with light-emitting devices. FIG. 12 describes several types of satisfactory light-emitting devices. In one embodiment the light-emitting devices can comprise an LED 150, an incandescent light 152, or a fluorescent lamp 154. Further, one skilled in the art will recognize other satisfactory embodiments.

### CONCLUSION

Aspects of the presently described embodiments include increasing the safety of a person transporting a portable computing device in low light conditions.

Although the invention has been described in language specific to structural features and/or methodological blocks, it is to be understood that the invention defined in the appended claims is not necessarily limited to the specific features or blocks described. Rather, the specific features and blocks are disclosed as preferred forms of implementing the claimed invention.

What is claimed is:

1. A safety device comprising:
a portable computer having a housing that can be opened for accessing the computer and closed for transporting the computer; and,
at least one light-emitting device positioned on the housing and configured to emit light of sufficient magnitude to be perceived by others when the housing is closed and the computer is carried by an individual.

2. The safety device of claim 1, wherein the housing when closed has a top surface and a bottom surface and side surfaces at least portions of which extend generally perpendicularly therebetween and at least one light-emitting device on at least one of said surfaces.

3. The safety device of claim 2, wherein the at least one light emitting device comprises multiple light emitting devices positioned on multiple surfaces of the computer housing.

4. The safety device of claim 3, wherein the multiple light emitting devices are positioned on all surfaces of the computer housing.

5. The safety device of claim 3, wherein the multiple light emitting devices are configured to blink in a predefined pattern.

6. The safety device of claim 1, wherein the at least one light emitting device comprises at least one LED.

7. The safety device of claim 1, wherein the at least one light emitting device comprises at least one incandescent light.

8. A safety device comprising:
a portable computer having a housing that can be opened for accessing the computer and closed for transporting the computer;
at least one light emitting device positioned on the housing and configured to emit light of sufficient magnitude to be perceived by others when the housing is closed and the computer is carried; and
a controller coupled with the at least one light emitting device to selectively enable or disable the at least one light emitting device.

9. The safety device of claim 8, wherein the controller comprises a user-activatable switch.

10. The safety device of claim 9, wherein the user-activatable switch comprises a user-activatable timer switch.

11. The safety device of claim 8, wherein the controller comprises a motion sensor switch.

12. The safety device of claim 8, wherein the controller comprises a light sensor switch.

13. The safety device of claim 8, wherein the controller comprises a motion sensor switch and a light sensor switch.

14. The safety device of claim 8, wherein the at least one light emitting device comprises at least one LED.

15. The safety device of claim 8, wherein the housing has at least one reflective surface.

16. The safety device of claim 15, wherein the at least one reflective surface comprises a specular reflective surface.

17. A portable computer comprising:
a housing;
a power source supported by the housing; and,
at least one light emitting device connected to the power source and configured to emit light responsive to the computer being carried.

18. The portable computer as claimed in claim 17, further comprising at least one reflective structure positioned on the housing.

19. The portable computer as claimed in claim 17, wherein the at least one light emitting device comprises multiple light emitting devices positioned on the housing so that at least some of them are visible when the computer is carried by a user.

20. The portable computer as claimed in claim 19, wherein the multiple light emitting devices are positioned on the housing so that some of the multiple light emitting devices are visible from multiple directions relative to a user when the computer is carried by the user.

21. The computer as claimed in claim 19, wherein the multiple light emitting devices are positioned on the housing so that light emitting devices are visible from a front position, a rear position, and at least one side position relative to a user when the computer is carried by the user.

22. The electronic safety device as claimed in claim 19, wherein the multiple light emitting devices are configured to blink in a predefined pattern.

23. A portable computer comprising:
a housing; and,
at least one light reflecting safety structure attached to the housing and positioned to reflect light in a manner that promotes the safety of an individual carrying the computer by making the individual more visible to others in the individual's proximity than the individual otherwise would be without the at least one light reflecting safety structure attached to the housing.

24. The portable computer safety structure of claim 23, wherein the at least one light reflecting safety structure comprises at least one specular reflector.

25. The portable computer safety structure of claim 23, wherein the at least one light reflecting safety structure comprises multiple discrete reflective structures arranged in a pattern.

26. A portable computer comprising:
a housing; and,
at least one light reflecting surface adhered to the housing and positioned to reflect light in a manner that promotes the safety of an individual carrying the computer by making the individual more visible to others in the individual's proximity than the individual otherwise would be without the at least one light reflecting safety structure adhered to the housing.

27. The portable computer of claim 26, wherein the at least one light reflecting surface has a high degree of specularity.

28. A method for protecting a person who transports a portable computer comprising:
providing a portable computer having a housing; and,
affixing at least one reflective structure to the housing, the reflective structure being positioned to reflect light so that the light can be seen by others when the computer is carried.

29. The method of claim 28, wherein affixing at least one reflective structure comprises affixing at least one specular reflective structure.

30. A method for protecting a person who transports a portable computer comprising:
providing a portable computer having a housing; and,
adhering at least one reflective surface to the housing, the surface being positioned to reflect light so that the light can be seen by others when the computer is carried.

31. The method of claim 30, wherein adhering at least one reflective surface comprises adhering at least one reflective surface which has a high degree of specularity.
